(19) United States
(12) Patent Application Publication
(10) Pub. No.: US 2026/0164549 A1
(43) Pub. Date: Jun. 11, 2026

(54) VERTICAL DEVICE EMBEDDED PRINTED CIRCUIT BOARDS WITH DOPED DIAMOND SUBSTRATE AND METHODS OF MANUFACTURING THE SAME

(71) Applicant: Toyota Motor Engineering & Manufacturing North America, Inc., Plano, TX (US)

(72) Inventors: Yohei Iwahashi, South Lyon, MI (US); Feng Zhou, Ann Arbor, MI (US); Tianzhu Fan, Houston, TX (US); Shailesh N. Joshi, Ann Arbor, MI (US); Ercan Mehmet Dede, Ann Arbor, MI (US)

(21) Appl. No.: 18/977,035

(22) Filed: Dec. 11, 2024

(51) Int. Cl. H05K 1/03; H05K 1/11; H05K 1/18; H05K 3/34; H05K 3/46

(52) U.S. Cl. CPC H05K 1/0306; H05K 1/116; H05K 1/183; H05K 3/34; H05K 3/4605; H05K 3/4644; H05K 3/4697; H05K 2201/064; H05K 2201/066; H05K 2201/09454; H05K 2201/10522

(57) ABSTRACT

A printed circuit board includes a cold plate and a diamond-based core layer bonded to the cold plate. The diamond-based core layer includes a diamond substrate with a conductive doped cave and a bare die disposed in and bonded to the conductive doped cave. Also, a circuit board layer with a conductive pattern is bonded to the diamond-based core layer and conductive through vias extend through the circuit board layer and are in direct contact with the bare die and the conductive doped cave.

### TECHNICAL FIELD

The present disclosure relates to printed circuit boards, and particularly to printed circuit boards with integrated circuits embedded therein.

### BACKGROUND

Printed circuit boards (PCBs) are typically used for mechanical support and electrical connection of electronic components using conductive pathways of copper sheets laminated onto a non-conductive substrate. And multi-layer PCBs provide higher capacity and/or density of electronic components in a smaller footprint by incorporating two or more layers. However, the design and fabrication of multilayer PCBs with desired heat dissipation can be difficult.

The present disclosure addresses issues related to the manufacture of multi-layer PCBs and other issues related to multi-layer PCBs.

### SUMMARY

This section provides a general summary of the disclosure and is not a comprehensive disclosure of its full scope or all of its features.

In one form of the present disclosure, a multi-layer printed circuit board includes a cold plate and a diamond-based core layer bonded to the cold plate. The diamond-based core layer includes a diamond substrate with a conductive doped cave and a bare die disposed in and bonded to the conductive doped cave. Also, a circuit board layer with a conductive pattern is bonded to the diamond-based core layer and conductive through vias extend through the circuit board layer and are in direct contact with the bare die and the conductive doped cave.

In another form of the present disclosure, a method includes forming a cave in a diamond substrate, conductive doping the cave and forming a conductive doped cave, bonding a vertical power device within the conductive doped cave and forming a diamond-based core layer, bonding the diamond-based core layer to a cold plate, and bonding a circuit board layer with a predefined conductive pattern to the diamond-based core layer. The method also includes forming conductive through vias in the circuit board layer such that at least one of the conductive through vias is in direct contact with the vertical power device and at least one of the conductive through vias is in direct contact with the conductive doped cave.

Further areas of applicability and various methods of enhancing the above technology will become apparent from the description provided herein. The description and specific examples in this summary are intended for purposes of illustration only and are not intended to limit the scope of the present disclosure.

### BRIEF DESCRIPTION OF THE DRAWINGS

The present teachings will become more fully understood from the detailed description and the accompanying drawings, wherein:

FIG. 1 shows a side cross-sectional view of a diamond-based chip-embedded printed circuit board (PCB) according to one form of the present disclosure;

FIG. 1A illustrates a step in manufacturing the diamond-based chip-embedded multi-layer PCB in FIG. 1;

FIG. 1B illustrates another step in manufacturing the diamond-based chip-embedded multi-layer PCB in FIG. 1;

FIG. 1C illustrates still another step in manufacturing the diamond-based chip-embedded multi-layer PCB in FIG. 1;

FIG. 1D illustrates yet another step in manufacturing the diamond-based chip-embedded multi-layer PCB in FIG. 1;

FIG. 1E illustrates still yet another step in manufacturing the diamond-based chip-embedded multi-layer PCB in FIG. 1;

FIG. 1F illustrates a step in manufacturing the diamond-based chip-embedded multi-layer PCB in FIG. 1;

FIG. 1G illustrates another step in manufacturing the diamond-based chip-embedded multi-layer PCB in FIG. 1;

FIG. 1H illustrates still another step in manufacturing the diamond-based chip-embedded multi-layer PCB in FIG. 1;

FIG. 1I illustrates yet another step in manufacturing the diamond-based chip-embedded multi-layer PCB in FIG. 1;

FIG. 1J illustrates still yet another step in manufacturing the diamond-based chip-embedded multi-layer PCB in FIG. 1;

FIG. 1K illustrates a step in manufacturing the diamond-based chip-embedded multi-layer PCB in FIG. 1;

FIG. 1L illustrates another step in manufacturing the diamond-based chip-embedded multi-layer PCB in FIG. 1;

FIG. 1M illustrates still another step in manufacturing the diamond-based chip-embedded multi-layer PCB in FIG. 1;

FIG. 1N illustrates yet another step in manufacturing the diamond-based chip-embedded multi-layer PCB in FIG. 1;

FIG. 1O illustrates still yet another step in manufacturing the diamond-based chip-embedded multi-layer PCB in FIG. 1;

FIG. 1P illustrates a step in manufacturing the diamond-based chip-embedded multi-layer PCB in FIG. 1;

FIG. 2 shows a side cross-sectional view of a diamond-based chip-embedded multi-layer PCB according to another form of the present disclosure;

FIG. 2A illustrates a step in manufacturing the diamond-based chip-embedded multi-layer PCB in FIG. 2;

FIG. 2B illustrates another step in manufacturing the diamond-based chip-embedded multi-layer PCB in FIG. 2;

FIG. 2C illustrates a still another step in manufacturing the diamond-based chip-embedded multi-layer PCB in FIG. 2;

FIG. 2D illustrates a yet another step in manufacturing the diamond-based chip-embedded multi-layer PCB in FIG. 2; and

FIG. 2E illustrates a still yet another step in manufacturing the diamond-based chip-embedded multi-layer PCB in FIG. 2.

It should be noted that the figures set forth herein are intended to exemplify the general characteristics of the methods and devices among those of the present technology, for the purpose of the description of certain aspects. The figures may not precisely reflect the characteristics of any given aspect and are not necessarily intended to define or limit specific forms or variations within the scope of this technology.

### DETAILED DESCRIPTION

The present disclosure provides diamond-based chip-embedded printed circuit boards (PCBs) and methods of manufacturing diamond-based chip-embedded multi-layer PCBs. As used herein, the term “diamond” refers to the solid form of carbon with a diamond cubic crystal structure and the phrase “diamond-based chip-embedded multi-layer PCB” refers to a multi-layer PCB module or unit with two or more diamond substrates (layers), two or more vertical power semiconductor devices (also referred to herein simply as “power device” or “power devices”) embedded at least partially within the two or more diamond substrates, control/drive/protection electronic circuitry, and passive components. Also, as used herein, the phrase “power device” refers to a semiconductor device (also known as a “chip”) used as a switch or rectifier in power electronics.

Diamond-based chip-embedded multi-layer PCBs according to the teachings of the present disclosure can include a cold plate with two or more diamond substrates bonded to the cold plate, and two or more vertical power devices embedded within one or more of the diamond substrates. For example, in some variations, the two or more vertical power devices are disposed at least partially within a diamond substrate to form a diamond-based core layer, a first surface of the diamond core layer is bonded directly to the cold plate, and additional diamond substrates, with predefined conductive patterns, are bonded to a second surface of the diamond-based core player.

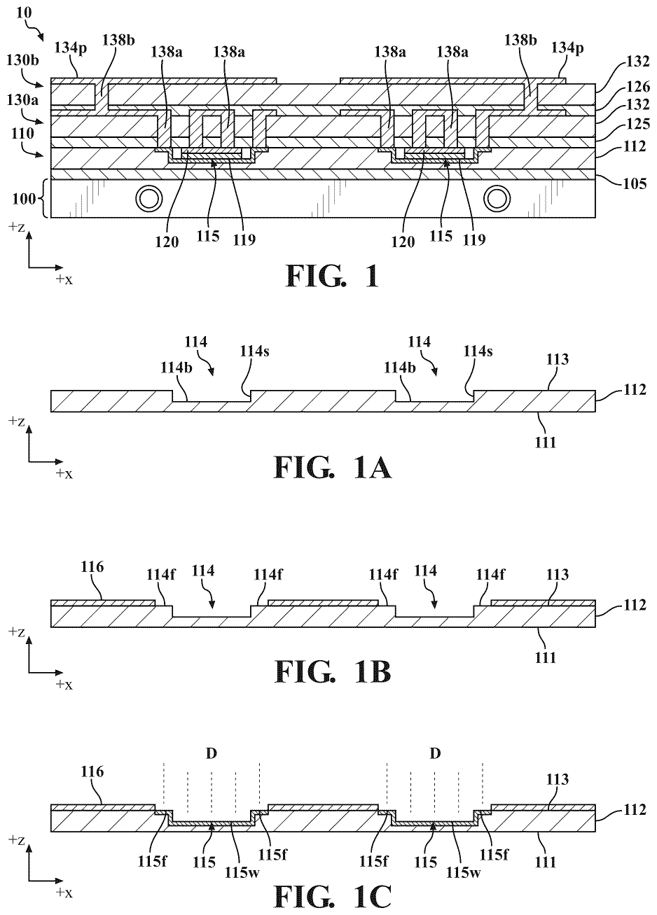

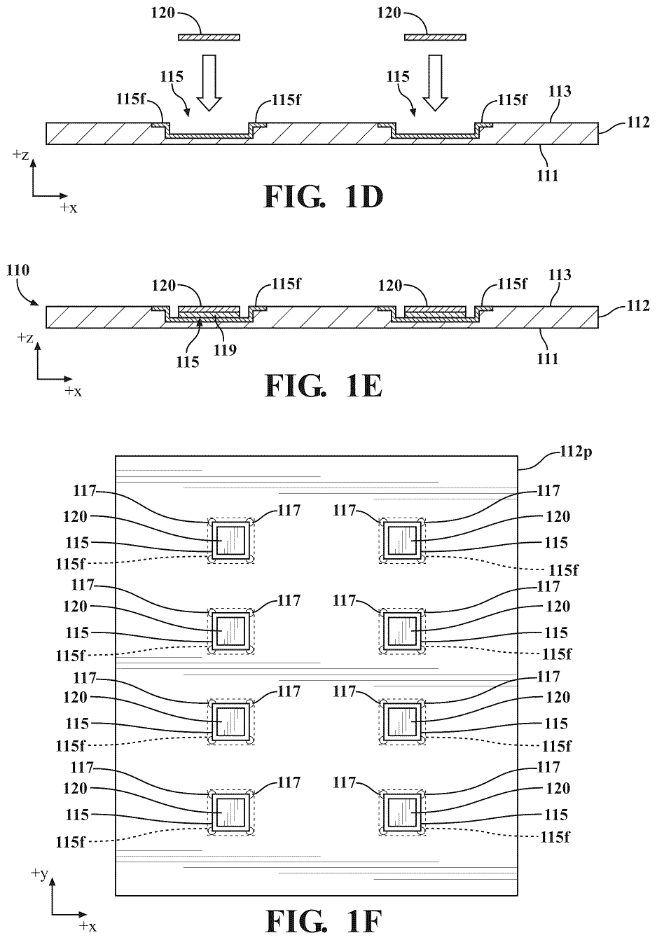

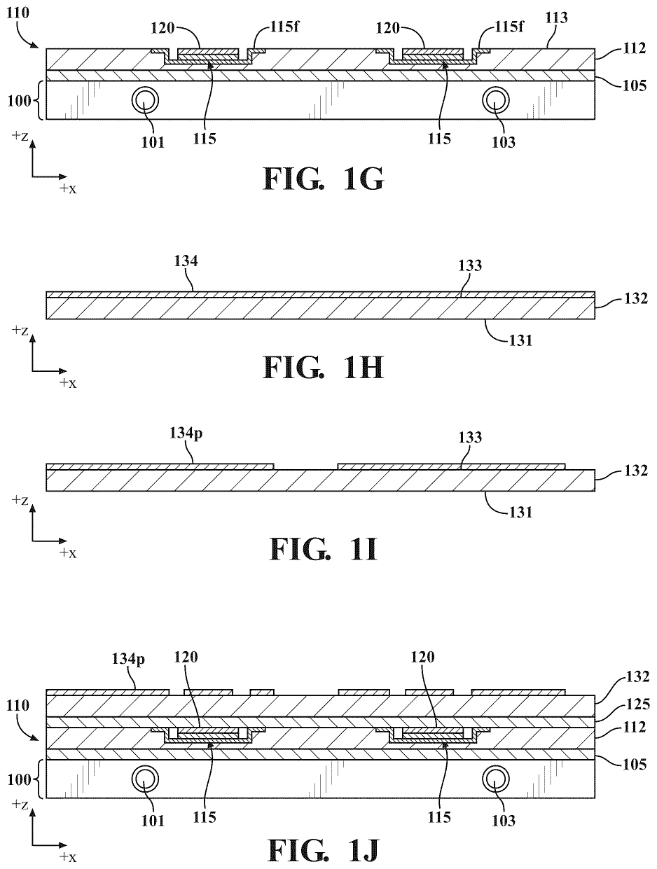

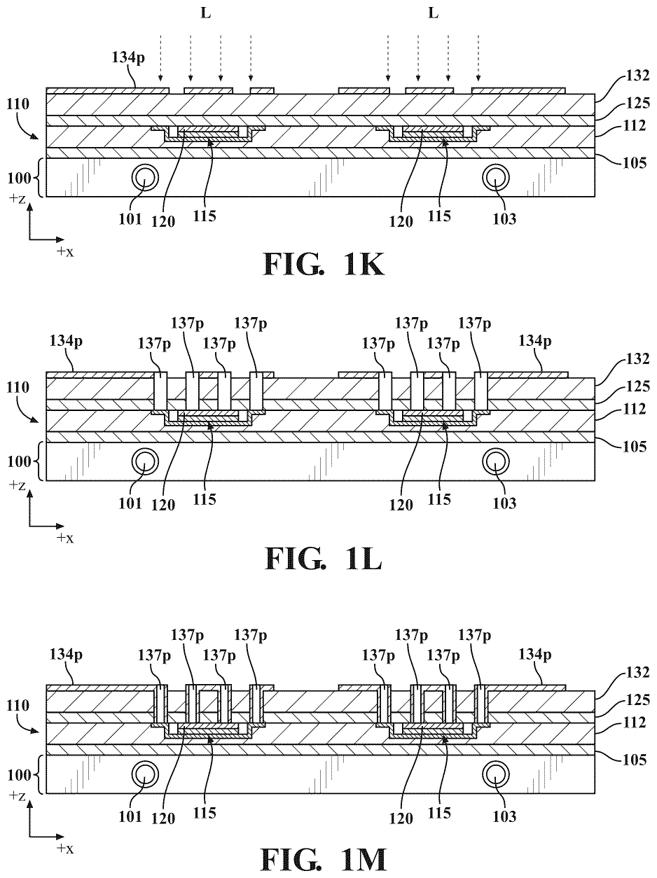

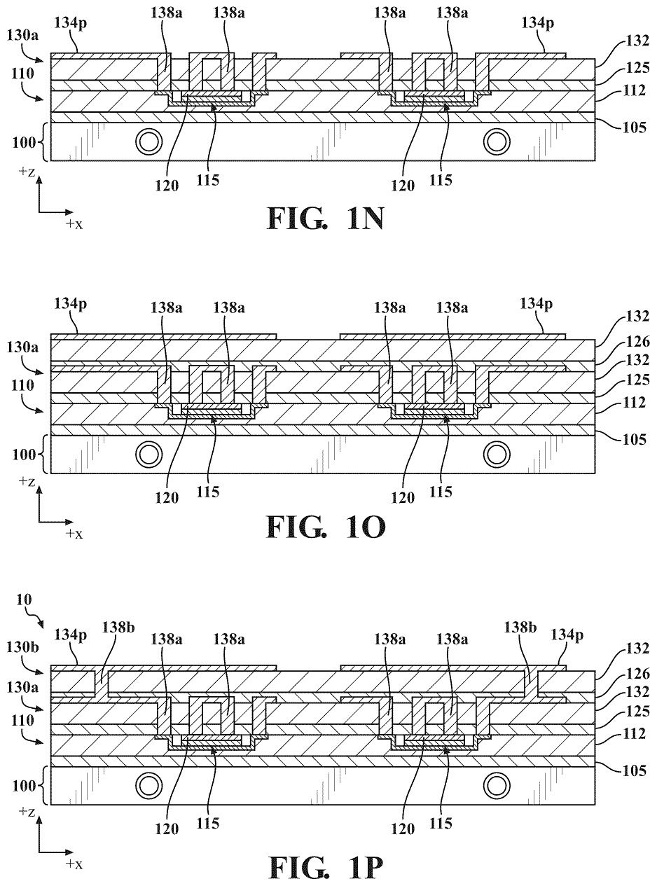

Referring now to FIG. 1, a cross-sectional view of an asymmetric chip-embedded multi-layer PCB in the form of a diamond-based chip-embedded multi-layer PCB 10 is shown. As used herein, the phrase “asymmetric chip-embedded multi-layer PCB” refers to a chip-embedded multi-layer PCB with a core layer not evenly positioned or disposed between a plurality of circuit board layers. That is, there are a greater number of circuit board layers bonded to one side of the core layer than are bonded to an opposite side of the core layer. As used herein, the phrase “circuit board layer” refers to PCB layer or substrate with control/drive/protection electronic circuitry and/or passive components, but without a power device embedded therein. Also, it should be understood that PCBs formed from traditional materials (e.g., FR4) typically require the manufacture of symmetric chip-embedded multi-layer PCBs, i.e., a core layer evenly positioned or disposed between a plurality of circuit board layers, due to a lack of stiffness of the PCB material and the PCB manufacturing process resulting in warping of the circuit board layers. In contrast, the stiffness (i.e., elastic modulus) of the diamond substrates according to the teachings of the present disclosure allows for the manufacture of asymmetric chip-embedded multi-layer PCBs without warping.

The diamond-based chip-embedded multi-layer PCB 10 includes a cold plate 100, a diamond-based core layer 110 and a plurality of diamond-based circuit board layers 130a-130b (collectively referred to herein as “diamond-based circuit board layers 130”). In some variations, the cold plate 100 is a fluid (e.g., water) cooled cold plate 100 with a fluid inlet 101 and a fluid outlet 103. In other variations, the cold plate 100 is a two-phase cooling device, a vapor chamber, or an air-cooled heat sink.

The diamond-based core layer 110 includes a diamond substrate 112 with two or more vertical bare dies 120 embedded and bonded the diamond substrate 112 via a bonding layer 116. As used herein, the phrase “bare die” refers to a semiconductor (e.g., silicon) chip that contains an integrated circuit and is not packaged in a protective enclosure, and the phrase “vertical bare die” refers to a bare die with a vertical architecture such that current flows from top (+z direction) to bottom (−z direction) of the bare die.

In some variations, the diamond substrate 112 includes two or more electrically conductive doped caves 115 (also referred to herein simply as “conductive doped cave” or “conductive doped caves”) and the vertical bare dies 120 are bonded directly to the conductive doped caves 115, i.e., a heat spreader is not present between the vertical bare dies 120 and the diamond substrate 112. It should be understood that traditional chip-embedded multi-layer PCBs typically require a heat spreader bonded to a bare die in order to enhance heat dissipation therefrom. However, the thermal conductivity of the diamond substrate 112 (˜2,220 W/(m·K)) provides enhanced heat conduction away from the vertical bare dies 120 such that heat spreaders are not present, and thereby simplifies the design and manufacture of a chip-embedded multi-layer PCB.

Each of the diamond-based circuit board layers 130 includes a diamond substrate 132 (also referred to herein as “diamond layer 132”), control/drive/protection electronic circuitry 134 (also referred to herein simply as “predefined conductive pattern 134p”), and one or more conductive through vias 138a, 138b (also referred to herein collectively as “conductive through vias 138”) extending between a lower (−z direction) surface and an upper (+z direction) surface of a given diamond layer 132. In some variations, one or more of the conductive through vias 138 is/are in direct contact with a vertical bare die 120 and one or more of the conductive through vias 138 is/are in direct contact with a conductive dope cave 115. During operation, electrical signals traverse along the predefined conductive patterns 134p and conductive through vias 138 to and from the vertical bare dies 120 such that data and instructions provide for the exchange of information between the vertical bare dies 120 and other electrical components.

Referring to FIGS. 1A-1N, steps for the manufacture of the diamond-based chip-embedded multi-layer PCB 10 according to one or more methods of the present disclosure are illustrated. With reference to FIG. 1A, one step of manufacturing the diamond-based chip-embedded multi-layer PCB 10 includes forming a cave 114 (e.g., two caves 114) in a diamond substrate 112. As used herein, the term “cave” refers to a depression or pocket within a diamond substrate 112. The diamond substrate 112 has a predefined thickness (z-direction), width (x-direction), and length (y-direction). In some variations, the diamond substrate 112 has a thickness between about 100 micrometers (μm) and about 1.0 millimeter (mm). For example, the glass substrate can have a thickness between about 100 μm and about 200 μm, between about 200 μm and about 300 μm, between about 300 μm and about 400 μm, between about 400 μm and about 500 μm, between about 500 μm and about 600 μm, between about 600 μm and about 700 μm, between about 700 μm and about 800 μm, between about 800 μm and about 900 μm, or between about 900 μm and about 1000 μm. And in at least one variation, the diamond substrate 112 has a thickness of about 150 μm.

The cave 114 extends from a second surface 113 towards a first surface 111 of the diamond substrate 112 and includes a base wall (surface) 114b and at least one side wall 114s. The cave 114 is formed using known or yet to be developed diamond cutting and machining techniques such as laser cutting ablation, waterjet cutting, rotary sawing, and girdle sawing, among others. In addition, the cave 114 has a predefined width (x-direction), length (y-direction), and depth (z-direction) such that a vertical bare die 120 can be disposed or seated within the cave 114. In some variations, the depth of the cave 114 is generally equal to a thickness (z-direction) of a vertical bare die 120 bonded thereto such that an upper (+z direction) surface of the vertical bare die 120 is generally planar with the second surface 113 of the diamond substrate 112 (FIG. 1E). In other variations, the depth of the cave 114 is greater than a thickness (z-direction) of a vertical bare die 120 bonded thereto such that an upper (+z direction) surface of the vertical bare die 120 is below (−z direction) the second surface 113 of the diamond substrate 112. And in at least one variation, the depth of the cave 114 is less than a thickness (z-direction) of a vertical bare die 120 bonded thereto such that an upper (+z direction) surface of the vertical bare die 120 is above (+z direction) the second surface 113 of the diamond substrate 112.

Referring to FIG. 1B, the second surface 113 of the diamond substrate is masked with a masking layer 119 such that the cave 114 and a ledge or flange 114f adjacent to and extending from the at least one side wall 114s of the cave 114 are exposed, i.e., not masked by the masking layer 119. And the cave 114, including the flange 114f, is doped with an electrically conductive material ‘D’ (also referred to herein as “conductively doped”) to form a conductive doped cave 115 as illustrated in FIG. 1C. The conductive doped cave 115 includes a well portion 115w and a flange 115f. That is, the base wall 114b and the at least one side wall 114s are conductively doped to form a well portion 115w and the flange 114f is conductively doped to form a flange 115f (collectively referred to herein as the conductive doped cave 115). Non-limiting examples of an electrically conductive material D include boron (B), phosphorus (P), nitrogen (N), and combinations thereof, among others. Accordingly the conductive doped cave 115 is a boron doped cave 115, a phosphorus doped cave 115, a nitrogen doped cave 115, and combinations thereof, among others.

The conductive doped cave 115 is formed using known or yet to be developed surface doping techniques such as chemical vapor deposition (CVD), physical vapor deposition (PVD), sputtering coating, and others. Also, the depth of the conductive material D, i.e., the depth or thickness of the dopant layer, in the well 115w and the flange 115f can range from about 0.1 μm to about 3.0 μm, and the concentration of the conductive material D within the doped layer of the well portion 115w and the flange 115f can range from about 10¹⁸ dopant atoms (D) per cubic centimeter to about 10²² dopant atoms (D) per cubic centimeter. For example, the thickness of the dopant layer can be about 0.5 μm and the concentration of the conductive material D can be about 10²⁰ cm⁻³. Referring to FIGS. 1D-1E, vertical bare dies 120 are bonded to the diamond substrate 112 to form a diamond-based core layer 110. For example, vertical bare dies 120 are desirably positioned within and bonded to conductive doped caves 115, and thereby bonded to the diamond substrate 112, with bonding layer 116. In some variations, the bonding layer 116 is an

electrically conductive layer such that the vertical bare dies 120 are in electrical contact with the conductive doped cave 115. Also, the vertical bare dies 120 can be bonded to the conductive doped caves 115 using high temperature bonding techniques such as active brazing and UV-assisted brazing, middle temperature bonding techniques such as anodic bonding and soldering, and low-room temperature bonding techniques such as surface activated bonding, UV-curable conductive adhesive bonding and conductive thermo-curable bonding.

Referring to FIG. 1F, in some variations a plurality of diamond-based core layers 110 are formed on or in a diamond panel 112p per the steps discussed above with respect to FIGS. 1A-1E. That is, a plurality of rows (x-direction) of conductive doped caves 115 are formed in the diamond panel 112p and a plurality of vertical bare dies 120 are desirably positioned at least partially within the conductive doped caves 115 and bonded to the diamond panel 112p as illustrated in FIG. 1F. And in such variations, stress relieve structures 117 can be formed at corners of the conductive doped caves 115 such that the initiation and/or propagation of cracks at the corners of the conductive doped caves 115 is inhibited. Also, the diamond panel 112p is cut, either before or after the steps discussed below with respect to FIGS. 1G-1O, along the x-direction and/or y-direction shown in the figures to provide a plurality diamond-based core layers 110.

Referring to FIG. 1G, another step for the manufacture of the diamond-based chip-embedded multi-layer PCB 10 includes bonding the diamond-based core layer 110 to the cold plate 100 via a bonding layer 105. In some variations, the bonding layer 105 is a dielectric layer that is thermally conductive and electrically insulating.

Referring to FIGS. 1H-1O, other steps for the manufacture of the diamond-based chip-embedded multi-layer PCB 10 are illustrated. For example, and with reference to FIG. 1H, forming an electrically conductive layer 134 (also referred to herein simply as “conductive layer 134”) on a first surface 131 (not shown) and/or on a second surface 133 of a diamond layer 132 is shown. The diamond layer 132 has a predefined thickness (z-direction), width (x-direction), and length (y-direction). In some variations, the diamond layer 132 has a thickness between about 75 micrometers (μm) and about 1.0 millimeter (mm). For example, the glass substrate can have a thickness between about 75 μm and about 150 μm, between about 150 μm and about 225 μm, between about 225 μm and about 300 μm, between about 300 μm and about 375 μm, between about 375 μm and about 450 μm, between about 450 μm and about 525 μm, between about 525 μm and about 600 μm, between about 600 μm and about 700 μm, or between about 700 μm and about 800 μm, between about 800 μm and about 900 μm, or between about 900 μm and about 1000 μm. And in at least one variation, the diamond layer 132 has a thickness of about 100 μm.

The conductive layer 134 is formed or applied to the diamond layer 132 using any method or technique known or yet to be discovered, including chemical vapor deposition (CVD), physical vapor deposition (PVD), sputtering coating, directed bonded copper (DBC), direct plated copper (DPC), stencil/vacuum plating, screen printing, and inkjet printing, among others. Also, the conductive layer 134 is formed from an electrically conducting material (e.g., copper (Cu), silver (Ag), or alloys thereof) and in some variations has a predefined thickness between about 35 micrometers (μm) and about 105 μm.

Referring to FIG. 1I, etching the conductive layer 134 to form a predefined conductive pattern 134p on the first surface 131 and/or on the second surface 133 of the diamond layer 132 is shown and bonding the diamond layer 132 with the predefined conductive pattern 134p to the diamond-based core layer 110 via bonding layer 125 is shown in FIG. 1J. In some variations, the bonding layer 125 is a dielectric layer that is thermally conductive and electrically insulating. Also, bonding of the diamond layer 132 to the diamond-based core layer 110 via bonding layer 125 can be performed using known or yet to be discovered bonding techniques such as adhesive bonding (UV or thermal curable), diamond frit bonding, among others. Accordingly, the bonding layer 125 can be an adhesive layer or a diamond frit layer, among others.

Referring to FIGS. 1K-1O, a laser ‘L’, or some other drilling device, drills or forms vias 137 in and through the diamond layer 132 (FIG. 1K), and predefined conductive pattern 134p if present, and bonding layer 125, and conductive through vias 138a are formed such that the predefined conductive pattern 134p is in electrical contact with the diamond-based core layer 110 (FIGS. 1M-1N). In this manner, the diamond-based circuit board layer 130a is formed and bonded to the diamond-based core layer 110. It should be understood that the steps for forming the diamond-based circuit board layer 130a can be performed or executed in a different order or sequence than as illustrated in FIGS. 1H-1N. For example, one alternative sequence can include forming the vias 137 and/or the conductive through vias 138 in the diamond layer 132 before the diamond layer 132 is bonded to the diamond-based core layer 110.

In some variations, the vias 137 are pre-treated with seed material (e.g., Cu) such that pre-treated vias 137p are formed (FIG. 1M), and then conductive material (e.g., Cu) is added to the pre-treated vias 137p to form the conductive through vias 138a. And in at least one variation, the conductive through vias 138a are in direct contact with a vertical bare die 120 and/or a conductive doped cave 115. For example, and as illustrated in FIG. 1N, at least one conductive through via 138a is in direct contact with a vertical bare die 120 and at least one conductive through vias 138a is in direct contact with a flange 115f of a conductive doped cave 115.

In some variations, and with reference to FIGS. 1O-1P, additional steps for the manufacture of the diamond-based chip-embedded multi-layer PCB 10 can include bonding another diamond layer 132 with a predefined conductive pattern 134p to the diamond-based circuit board layer 130a such that diamond-based circuit board layer 130b is formed. It should be understood that the diamond-based circuit board layer 130b can be formed as described above with respect to diamond-based circuit board layer 130a, i.e., a conductive layer 134 is formed or applied to the diamond layer 132, the conductive layer 134 is etched to form a predefined conductive pattern 134p, and the diamond layer 132 with the conductive pattern 134p is bonded to the diamond-based circuit board layer 130a via bonding layer 126. Also, a laser ‘L’, or some either drilling device, drills or forms vias 137 in and through the predefined diamond layer 132, and predefined conductive pattern 134p if present, and the bonding layer 126. The vias 137 may or may not be pre-treated with seed material (e.g., Cu) such that pre-treated vias 137p are formed (FIG. 1L), and conductive material (e.g., Cu) is added to the vias 137 or pre-treated vias 137p to form the conductive through vias 138b. And as noted above with respect to forming the diamond-based circuit board layer 130a, it should be understood that the steps for forming the diamond-based circuit board layer 130b can be performed or executed in a different order or sequence.

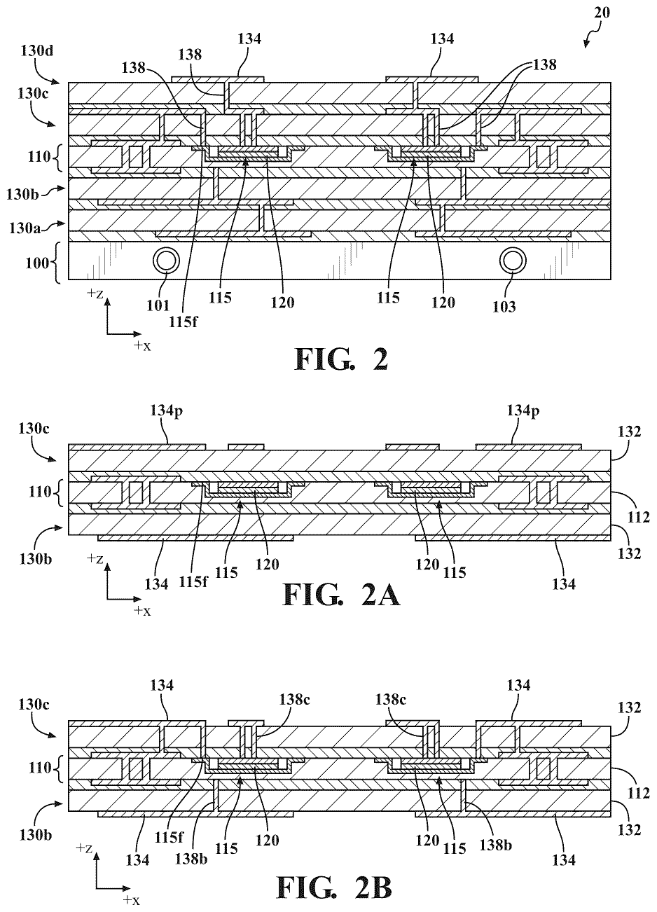

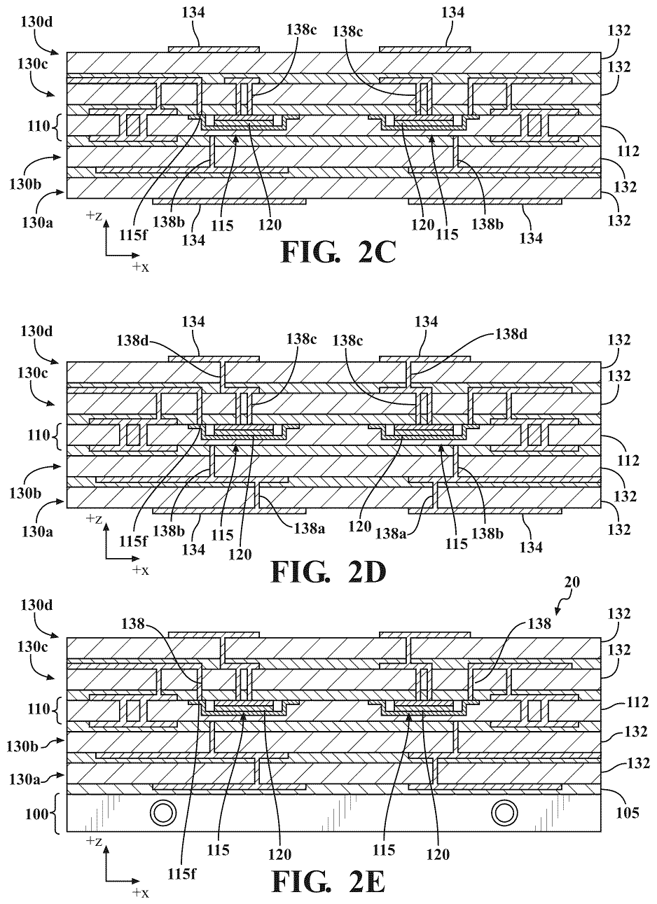

Referring now to FIG. 2, a cross-sectional view of a symmetric multi-layer PCB in the form of a diamond-based chip-embedded multi-layer PCB 20 is shown. The diamond-based chip-embedded multi-layer PCB 20 includes the cold plate 100, the diamond-based core layer 110 and a plurality of diamond-based circuit board layers 130a-130d (collectively referred to herein as “diamond-based circuit board layers 130”). However, and unlike the diamond-based chip-embedded multi-layer PCB 10, the diamond-based core layer 110 is disposed or positioned evenly between the diamond-based circuit board layers 130a-130d such the diamond-based chip-embedded multi-layer PCB 20 is symmetric. That is, two diamond-based circuit board layers (130a, 130b) are positioned and bonded below (−z direction) the diamond-based core layer 110 and two diamond-based circuit board layers (130c, 130d) are positioned and bonded above (+z direction) the diamond-based core layer 110.

Referring to FIGS. 2A-2E, steps for the manufacture of the diamond-based chip-embedded multi-layer PCB 20 are illustrated. Particularly, and with reference to FIG. 2A, one step of manufacturing the diamond-based chip-embedded multi-layer PCB 20 includes bonding a diamond layer 132 with a predefined conductive pattern 134p to the first surface 111 of the diamond-based core layer 110 (i.e., diamond substrate 112) via bonding layer 126 and bonding another diamond layer 132 with a predefined conductive pattern 134p to the second surface 113 of the diamond-based core layer 110 via bonding layer 127. It should be understood that the diamond-based core layer 110 can be formed of fabricated per the steps described above with respect to FIGS. 1A-1E and diamond layers 132 with predefined conductive patterns 134p can be formed or fabricated per the steps described with reference to FIG. 1H-1I. In addition, conductive through vias 138b, 138c are formed through the diamond layers 132 (FIG. 2B) such that diamond-based circuit board layers 130b, 130c are formed. And as illustrated in FIG. 2B, in some variations one or more of the conductive through vias 138b are in direct contact with a vertical bare die 120 and one or more of the conductive through vias 138c are in direct contact with a flange 115f of a conductive doped cave 115. In this manner, two diamond-based circuit board layers 130 are bonded to the diamond-based core layer 110 symmetrically.

Referring to FIG. 2C, additional steps for the manufacture of the diamond-based chip-embedded multi-layer PCB 20 include bonding a diamond layer 132 with a predefined conductive pattern 134p to the lower (−z direction) of the diamond-based circuit board layer 130b via bonding layer 125 and bonding another diamond layer 132 with a predefined conductive pattern 134p to the upper (+z direction) of the diamond-based circuit board layer 130c via bonding layer 128. And referring to FIG. 2D, additional steps include forming conductive through vias 138a, 138d through the diamond-based circuit board layers 130a, 130d, respectively. Then, and with reference to FIG. 2E, the upper (+z direction) surface of the cold plate 100 is bonded to the lower (−z direction) surface of the diamond-based circuit board layer 130a via bonding layer 105. In this manner, the diamond-based chip-embedded multi-layer PCB 20 is manufactured.

The preceding description is merely illustrative in nature and is in no way intended to limit the disclosure, its application, or its uses. Work of the presently named inventors, to the extent it may be described in the background section, as well as aspects of the description that may not otherwise qualify as prior art at the time of filing, are neither expressly nor impliedly admitted as prior art against the present technology.

The figures illustrate the functionality and operation of possible implementations of methods and systems according to various forms or variations. In this regard, each block in the block diagram may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved.

As used herein, the phrase at least one of A, B, and C should be construed to mean a logical (A or B or C), using a non-exclusive logical “or.” It should be understood that the various steps within a method may be executed in different order without altering the principles of the present disclosure. Disclosure of ranges includes disclosure of all ranges and subdivided ranges within the entire range.

The headings (such as “Background” and “Summary”) and sub-headings used herein are intended only for the general organization of topics within the present disclosure and are not intended to limit the disclosure of the technology or any aspect thereof. The recitation of multiple variations or forms having stated features is not intended to exclude other variations or forms having additional features, or other variations or forms incorporating different combinations of the stated features.

As used herein the term “about” when related to numerical values herein refers to known commercial and/or experimental measurement variations or tolerances for the referenced quantity. In some variations, such known commercial and/or experimental measurement tolerances are +/−10% of the measured value, while in other variations such known commercial and/or experimental measurement tolerances are +/−5% of the measured value, while in still other variations such known commercial and/or experimental measurement tolerances are +/−2.5% of the measured value. And in at least one variation, such known commercial and/or experimental measurement tolerances are +/−1% of the measured value.

The terms “a” and “an,” as used herein, are defined as one or more than one. The term “plurality,” as used herein, is defined as two or more than two. The term “another,” as used herein, is defined as at least a second or more. The terms “including” and/or “having,” as used herein, are defined as comprising (i.e., open language). The phrase “at least one of . . . and . . . ” as used herein refers to and encompasses any and all possible combinations of one or more of the associated listed items. As an example, the phrase “at least one of A, B, and C” includes A only, B only, C only, or any combination thereof (e.g., AB, AC, BC, or ABC).

As used herein, the terms “comprise” and “include” and their variants are intended to be non-limiting, such that recitation of items in succession or a list is not to the exclusion of other like items that may also be useful in the devices and methods of this technology. Similarly, the terms “can” and “may” and their variants are intended to be non-limiting, such that recitation that a form or variation can or may comprise certain elements or features does not exclude other forms or variations of the present technology that do not contain those elements or features.

The broad teachings of the present disclosure can be implemented in a variety of forms. Therefore, while this disclosure includes particular examples, the true scope of the disclosure should not be so limited since other modifications will become apparent to the skilled practitioner upon a study of the specification and the following claims. Reference herein to one variation, or various variations means that a particular feature, structure, or characteristic described in connection with a form or variation or particular system is included in at least one variation or form. The appearances of the phrase “in one variation” (or variations thereof) are not necessarily referring to the same variation or form. It should also be understood that the various method steps discussed herein do not have to be conducted in the same order as depicted, and not each method step is required in each variation or form.

The foregoing description of the forms and variations has been provided for purposes of illustration and description. It is not intended to be exhaustive or to limit the disclosure. Individual elements or features of a particular form or variation are generally not limited to that particular form or variation, but, where applicable, are interchangeable and can be used in a selected form or variation, even if not specifically shown or described. The same may also be varied in many ways. Such variations should not be regarded as a departure from the disclosure, and all such modifications are intended to be included within the scope of the disclosure.

What is claimed is:

1. A printed circuit board comprising:
a cold plate;
a diamond-based core layer bonded to the cold plate, the diamond-based core layer comprising a diamond substrate with a conductive doped cave, and a bare die disposed in and bonded to the conductive doped cave;
a circuit board layer with a conductive pattern bonded to the diamond-based core layer; and
conductive through vias extending through the circuit board layer and in direct contact with the bare die and the conductive doped cave.

2. The printed circuit board according to claim 1, wherein the circuit board layer is a diamond-based circuit board layer.

3. The printed circuit board according to claim 2 further comprising an another circuit board layer bonded to the diamond-based core layer.

4. The printed circuit board according to claim 3, wherein the another circuit board layer is an another diamond-based circuit board layer.

5. The printed circuit board according to claim 1, wherein the circuit board layer is a first circuit board layer and further comprising a second circuit board layer bonded to the first circuit board layer.

6. The printed circuit board according to claim 5, wherein the first circuit board layer is a first diamond-based circuit board layer.

7. The printed circuit board according to claim 5, wherein the second circuit board layer is a second diamond-based circuit board layer.

8. The printed circuit board according to claim 1, wherein the conductive doped cave is selected from the group consisting of a boron doped cave, a phosphorus doped cave, a nitrogen doped cave, and combinations thereof.

9. The printed circuit board according to claim 1, wherein the conductive doped cave extends from a second surface of the diamond substrate towards a first surface oppositely disposed from the second surface.

10. The printed circuit board according to claim 9, wherein the conductive doped cave comprises a well and a flange.

11. The printed circuit board according to claim 10, wherein at least one of the conductive through vias extending through the circuit board layer is in direct contact with the flange of the conductive doped cave.

12. The printed circuit board according to claim 1, wherein the bare die is a vertical power device.

13. The printed circuit board according to claim 1, wherein the conductive doped cave is a pair of conductive doped caves and the bare die is a pair of bare dies disposed in and bonded to the pair of conductive doped caves such that each of the pair of conductive doped caves has one of the pair of bare dies bonded thereto.

14. The printed circuit board according to claim 13, wherein the pair of bare dies is a pair of vertical power devices.

15. A method comprising:
forming a cave in a diamond substrate;
conductive doping the cave and forming a conductive doped cave;
bonding a vertical power device within the conductive doped cave and forming a diamond-based core layer;
bonding the diamond-based core layer to a cold plate;
bonding a circuit board layer with a predefined conductive pattern to the diamond-based core layer; and
forming conductive through vias in the circuit board layer such that at least one of the conductive through vias is in direct contact with the vertical power device and at least one of the conductive through vias is in direct contact with the conductive doped cave.

16. The method according to claim 15, wherein conductive doping the cave comprises conductive doping a well of the cave and a flange of the cave.

17. The method according to claim 16, wherein conductive doping the cave comprises one or more of boron doping the cave, phosphorus doping the cave, and nitrogen doping the cave.

18. The method according to claim 15, wherein bonding the vertical power device within the conductive doped cave comprises surface activated bonding or soldering the vertical power device within the conductive doped cave.

19. The method according to claim 15, wherein the circuit board layer is a diamond-based circuit board layer.

20. The method according to claim 19 further comprising bonding another diamond-based circuit board layer to the diamond-based circuit board layer.
